(19) United States
(12) Patent Application Publication
(10) Pub. No.: US 2025/0079282 A1
(43) Pub. Date: Mar. 6, 2025

(54) PACKAGES WITH NOTCHED, INTERDIGITATED, AND RETRACTED METAL LAYERS

(71) Applicant: TEXAS INSTRUMENTS INCORPORATED, Dallas, TX (US)

(72) Inventors: John Carlo C. MOLINA, Limay (PH); Ruby Ann M. CAMENFORTE, Pampamga (PH)

(21) Appl. No.: 18/459,174

(22) Filed: Aug. 31, 2023

(51) Int. Cl. H01L 23/498; H01L 21/48; H01L 21/56; H01L 23/31

(52) U.S. Cl. CPC H01L 23/49822; H01L 21/4857; H01L 21/561; H01L 23/3121; H01L 23/49894; H01L 24/16; H01L 2224/16227

(57) ABSTRACT

In examples, a package comprises a semiconductor die having a device side including circuitry formed therein. The package comprises a substrate facing and coupled to the device side. The substrate includes first and second metal layers. The first metal layer is positioned closer to the device side than the second metal layer and is coupled to the second metal layer by way of a via. At least one of the first and second metal layers has a top surface facing the semiconductor die. The top surface includes a notch etched therein. The substrate also includes a dielectric contacting the notch and at least part of the first and second metal layers and the via. The package includes a mold compound covering the semiconductor die and the substrate. The package includes a lateral surface approximately perpendicular to the first and second metal layers of the substrate. The mold compound, the dielectric, and the second metal layer are exposed to the lateral surface. A segment of the dielectric is positioned between the first metal layer and the lateral surface. The segment of the dielectric contacts the mold compound at the lateral surface.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation.

### SUMMARY

In examples, a package comprises a semiconductor die having a device side including circuitry formed therein. The package comprises a substrate facing and coupled to the device side. The substrate includes first and second metal layers. The first metal layer is positioned closer to the device side than the second metal layer and is coupled to the second metal layer by way of a via. At least one of the first and second metal layers has a top surface facing the semiconductor die. The top surface includes a notch etched therein. The substrate also includes a dielectric contacting the notch and at least part of the first and second metal layers and the via. The package includes a mold compound covering the semiconductor die and the substrate. The package includes a lateral surface approximately perpendicular to the first and second metal layers of the substrate. The mold compound, the dielectric, and the second metal layer are exposed to the lateral surface. A segment of the dielectric is positioned between the first metal layer and the lateral surface. The segment of the dielectric contacts the mold compound at the lateral surface.

In examples, a method of manufacturing a package comprises forming a package substrate. Forming the package substrate includes: plating first and second metal layers in a first metal stack and a third metal layer in a second metal stack, the second metal layer having a lateral end that is displaced from a saw street closest to the lateral end by a distance of at least 100 microns, at least one metal layer in the first metal stack partially overlapping in a vertical direction with the third metal layer; applying a dry film to at least one of the first, second, and third metal layers; patterning the dry film to form a dry film opening; etching at least one of the first, second, and third metal layers through the dry film opening to form a notch; removing the dry film; plating the notch; and applying a dielectric layer to at least one of the first, second, and third metal layers. The method also includes: coupling a semiconductor die to the package substrate; covering the die and the substrate with a mold compound; and sawing along the saw street so as to saw through the mold compound and the dielectric layer, but not through the second metal layer.

### BRIEF DESCRIPTION OF THE DRAWINGS

FIG. 1 is a block diagram of an electronic device containing a semiconductor package with notched, interdigitated, and retracted metal layers, in accordance with various examples.

FIG. 2A is a cross-sectional view of a semiconductor package with notched, interdigitated, and retracted metal layers, in accordance with various examples.

FIG. 2B is a top-down view of a semiconductor package with notched, interdigitated, and retracted metal layers, in accordance with various examples.

FIG. 2C is a perspective view of a semiconductor package with notched, interdigitated, and retracted metal layers, in accordance with various examples.

FIG. 2D is a profile view of a semiconductor package with notched, interdigitated, and retracted metal layers, in accordance with various examples.

FIG. 2E is a bottom-up view of a semiconductor package with notched, interdigitated, and retracted metal layers, in accordance with various examples.

FIGS. 3A and 3B are a flow diagram of a method for manufacturing a semiconductor package with notched, interdigitated, and retracted metal layers, in accordance with various examples.

FIGS. 4A-4X are a process flow for manufacturing a semiconductor package with notched, interdigitated, and retracted metal layers, in accordance with various examples.

### DETAILED DESCRIPTION

Many semiconductor packages include a semiconductor die and conductive terminals exposed to an exterior surface of the package. The semiconductor die exchanges electrical signals with the conductive terminals so the die can communicate with components outside of the package, such as other chips that may be co-mounted on a printed circuit board (PCB) with the package. To provide electrical pathways between the semiconductor die and the conductive terminals, various structures may be useful, such as bond wires, redistribution layers, etc.

Some packages contain a substrate that has multiple metal layers (also known as a metal stack) to provide the aforementioned electrical pathway between the semiconductor die and the conductive terminals. In such packages, electrical currents may flow from the conductive terminal, through the metal stack in the substrate, and to the semiconductor die, or from the semiconductor die, through the metal stack in the substrate, and to the conductive terminal. Such substrates may contain a network of metal layers that are covered by an insulative film, such as AJINOMOTO® build-up film (ABF). These substrates are manufactured by forming a first metal layer, covering the first metal layer with ABF, then forming a second metal layer and covering the second metal layer with ABF, and so on, until a fully customized substrate is formed. Such substrates provide significant design flexibility.

Generally, during manufacture, the substrates are formed in sets or arrays, and then sets or arrays of semiconductor dies are coupled to the sets or arrays of substrates, with one semiconductor die coupled to each substrate. A mold compound is applied to cover the semiconductor dies and the substrates, thus forming a mold compound bar that contains within it the array of semiconductor dies and substrates. The mold compound bar has saw streets or other markings that indicate where singulation should occur to separate the substrates and dies from each other to form individual semiconductor packages.

In some cases, the metal layers in the substrates are formed in vertical alignment with the saw streets. Stated another way, when a sawing process is performed on the mold compound bar, the sawing tool (e.g., mechanical saw or laser) cuts through the metal layers of the substrate as the sawing tool cuts through the mold compound bar. This act of cutting through the metal layers, particularly when those metal layers are positioned in vertical proximity to the interface between the mold compound and the substrate film, imparts substantial stress to the mold compound bar. This stress is significant enough to cause irreparable damage to the mold compound bar, especially at the mold compound-substrate interface. For example, significant delamination may occur. These deleterious effects reduce yield and present a meaningful technical problem.

Furthermore, stresses experienced during sawing, during handling or use, and in various other conditions can introduce cracks into the package. For example, cracks may originate in a particular area of substrate dielectric material in the package, and then the cracks may extend themselves by propagating through the dielectric. Poor mechanical coupling between metal layers and dielectric material within the package can also encourage crack formation. Such cracks pose another meaningful technical problem. Together, delamination and cracking substantially reduce the robustness of semiconductor packages and represent significant technical challenges in the semiconductor industry.

This disclosure describes various examples of packages with notched, interdigitated, and retracted substrate metal layers. In examples, a package includes a semiconductor die having a device side including circuitry formed therein. The package includes a substrate facing and coupled to the device side. The substrate includes first and second metal layers, and the first metal layer is positioned closer to the device side than the second metal layer and is coupled to the second metal layer by way of a via. At least one of the first and second metal layers has a top surface facing the semiconductor die. The top surface includes a notch etched therein. The substrate also includes third and fourth metal layers. The third metal layer is positioned closer to the device side than the fourth metal layer, with the third and fourth metal layers spaced apart from the first and second metal layers. The first metal layer is at least partially overlapping the fourth metal layer in the vertical direction. The first and fourth metal layers are in different levels of the substrate. The substrate further includes a dielectric contacting at least part of the first and second metal layers and the via. The package includes a mold compound covering the semiconductor die and the substrate. The package includes a lateral surface approximately perpendicular to the first and second metal layers of the substrate. The mold compound, the dielectric, and the second metal layer are exposed to the lateral surface. A segment of the dielectric is positioned between the first metal layer and the lateral surface. The segment of the dielectric contacts the mold compound at the lateral surface. These and other examples are now described with reference to the drawings.

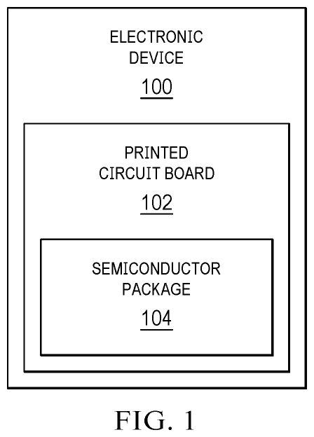

FIG. 1 is a block diagram of an electronic device 100 containing a semiconductor package with notched, interdigitated, and retracted metal layers, in accordance with various examples. More specifically, the electronic device 100 includes a printed circuit board (PCB) 102 on which a semiconductor package 104, such as a semiconductor package with notched, interdigitated, and retracted metal layers, is mounted. The electronic device 100 may be any suitable type of device, such as a computer (e.g., laptop, desktop, notebook, tablet, smartphone), a consumer electronic device (e.g., television, audio devices, security systems), appliances, automobiles, aircraft, spacecraft, etc., although the scope of this disclosure is not limited as such, and the semiconductor package 104 may be useful in any of a variety of contexts not expressly mentioned herein.

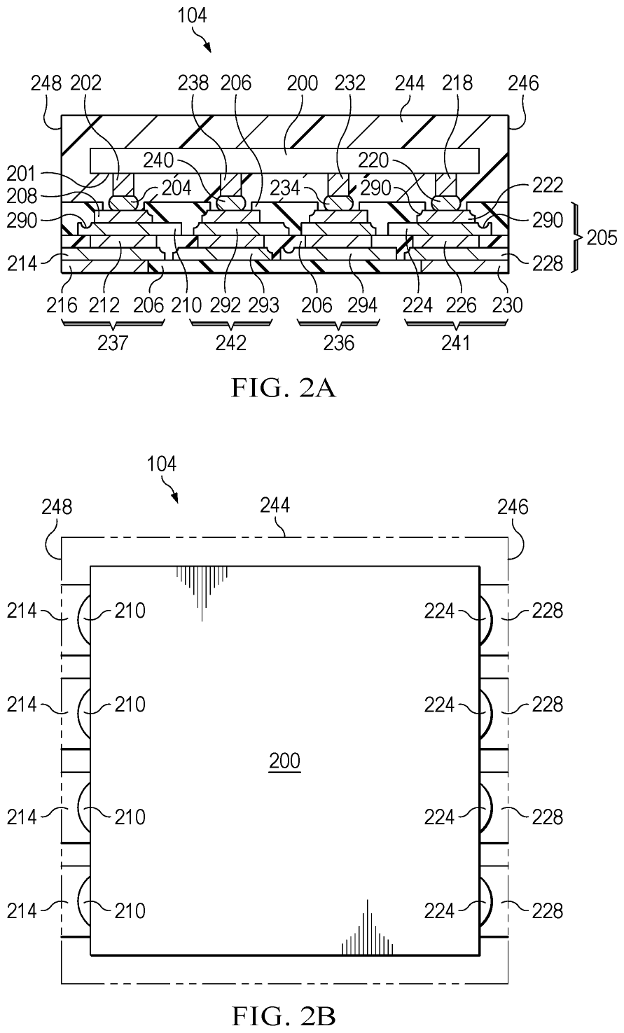

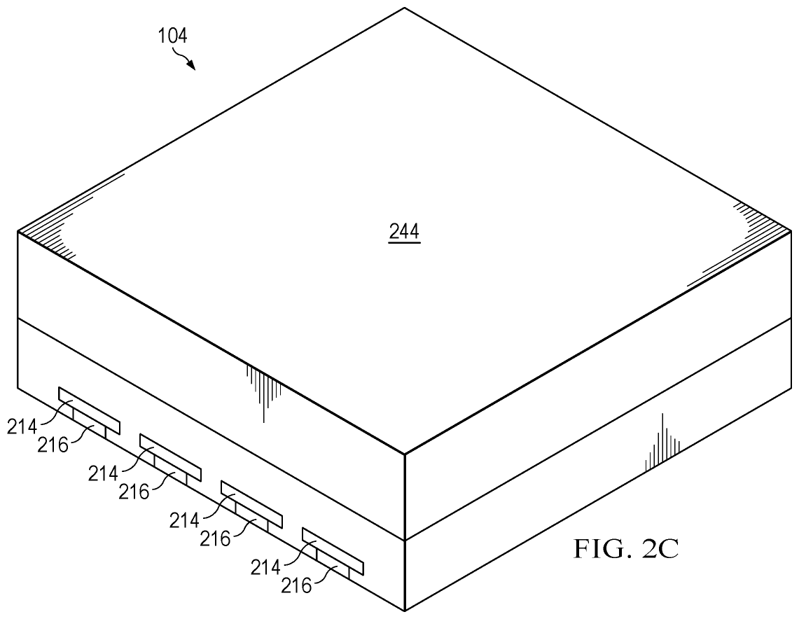

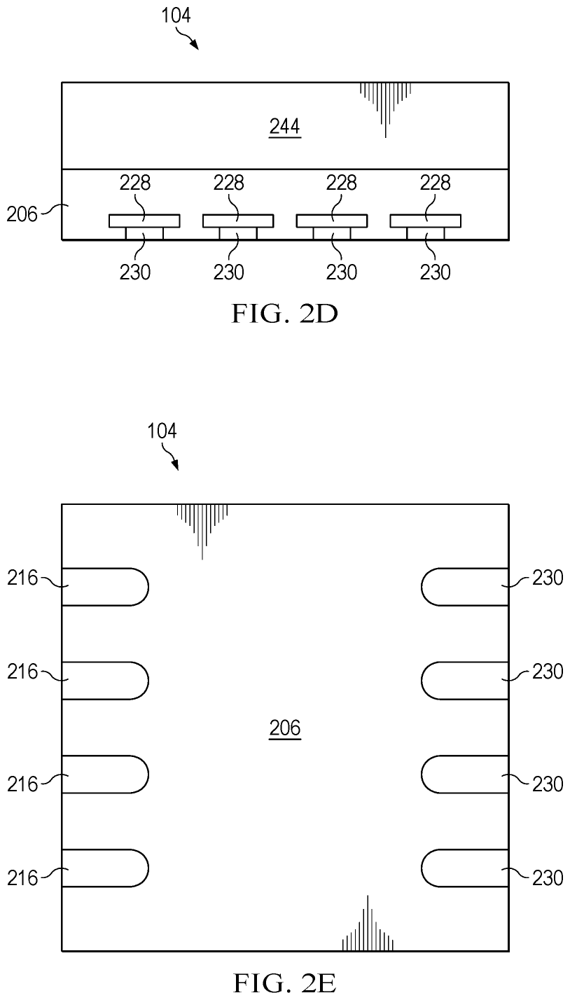

FIG. 2A is a cross-sectional view of a semiconductor package 104 with notched, interdigitated, and retracted metal layers, in accordance with various examples. The semiconductor package 104 comprises a semiconductor die 200 including a device side 201 having circuitry formed therein, and a non-device side opposing the device side 201. The semiconductor package 104 further comprises conductive members 202, 218, 232, and 238 coupled to the device side 201. In examples, the conductive members 202, 218, 232, and 238 are copper members (e.g., copper pillars), although any conductive material in any suitable shape may be useful. The semiconductor package 104 includes solder bumps 204, 220, 234, 240 coupled to the conductive members 202, 218, 232, 238, respectively, to provide electrical pathways between the conductive members 202, 218, 232, 238 and metal layers in a substrate of the semiconductor package 104, as now described.

The semiconductor package 104 includes a substrate 205. The substrate 205 comprises dielectric material 206 and a network of metal layers designed to implement application-specific electrical pathways (e.g., electrical pathways between solder bumps 204, 220, 234, 240 and metal layers exposed to a surface of the semiconductor package 104 to facilitate communications with devices outside of the semiconductor package 104). The dielectric material 206 may comprise, for example, AJINOMOTO® build-up film (ABF), although other films and materials with similar properties are contemplated. The network of metal layers includes internal metal stacks 236 and 242, which are positioned away from lateral surfaces of the semiconductor package 104. The network of metal layers also includes external metal stacks 237 and 241, which are positioned adjacent to the lateral surfaces of the semiconductor package 104. The metal layers in the metal stacks 236, 237, 241, and 242 may comprise any suitable metal, such as the plateable metals aluminum and copper.

The substrate 205 differs from a PCB because the substrate 205 is within the semiconductor package 104, whereas the PCB (e.g., PCB 102) is outside the semiconductor package 104. The substrate 205 includes multiple metal layers that are covered by a solid, tangible dielectric material 206, whereas the PCB may contain multiple layers of printed circuit board that may not be separated by a dielectric material other than air.

The metal stack 237 includes metal layers 208, 210, 212, 214, and 216. Some of the metal layers 208, 210, 212, 214, and 216 may comprise metal traces and others of these metal layers may comprise metal vias, but this distinction between metal traces and vias is minimally relevant in this disclosure, and they are collectively referred to herein as “metal layers.” The metal stack 241 includes metal layers 222, 224, 226, 228, and 230. Some of the metal layers 222, 224, 226, 228, and 230 may comprise metal traces and others of these metal layers may comprise metal vias, but this distinction between metal traces and vias is minimally relevant in this disclosure, and they are collectively referred to herein as “metal layers.” Solder bumps 204 and 220 couple to metal layers 208 and 222, respectively. Solder bumps 234 and 240 couple to the top metal layers in metal stacks 236 and 242, respectively. The semiconductor package 104 may be coupled to a PCB, such as PCB 102 (FIG. 1), by soldering the metal layers 216 and 230 to the PCB 102. A mold compound 244 covers the various structures of FIG. 2A.

As FIG. 2A shows, at least some of the metal layers in the metal stacks adjacent to lateral surfaces of the semiconductor package 104 are retracted from the lateral surfaces. For example, the metal layers 222, 224 and 226 could have been formed to interface with a lateral surface 246, but instead, the metal layers 222, 224 and 226 are deliberately formed to be offset, or retracted, from the lateral surface 246 by a predetermined distance, with the offset being filled by dielectric material 206. This retraction of the metal layers 222, 224 and 226 from the lateral surface 246 is beneficial because the amount of metal sawn during the singulation process is significantly reduced. Thus, the deleterious stresses (and related consequences, such as delamination) described above that would normally be introduced by the process of sawing through metal are mitigated. The retraction of a metal layer 224 from a closest lateral surface must be at least 100 microns (at least 125 microns in the case of metal layers 222, 226) to achieve this benefit. More generally, the metal layer 224 must be at least 100 microns (at least 125 microns in the case of metal layers 222, 226) away from every lateral surface of the semiconductor package 104 to achieve the benefit. In the case that a metal layer 224 is adjacent to two lateral surfaces, such as when the metal layer is near a corner of the semiconductor package 104, the metal layer 224 must be retracted from both lateral surfaces by at least 100 microns (at least 125 microns in the case of metal layers 222, 226) to achieve the benefits described above. These retractions of the metal layers from their respective lateral surfaces are implemented during manufacture of the semiconductor package 104, prior to the singulation (i.e., sawing) process.

Similar to the retraction of the metal layers 222, 224 and 226, the retraction of the metal layers 208, 210, and 212 from a closest lateral surface (such as lateral surface 248) is beneficial for similar reasons, and the retraction of the metal layer 210 from the closest lateral surface (e.g., lateral surface 248) is at least 100 microns (at least 125 microns in the case of metal layers 208, 212) to achieve the benefits described herein, with the area between these metal layers and the lateral surface 248 being filled with dielectric material. In examples, the various metal layers lie in horizontal planes that are perpendicular to the lateral surfaces 246 and 248. In examples, the mold compound 244 contacts the dielectric material 206 at the lateral surfaces 246, 248.

Multiple metal layers in the metal stacks 237, 242, 236, and 241 may be interdigitated. The term “interdigitated” means that two metal layers in different metal stacks partially overlap with each other in the vertical direction. Stated another way, a vertical line extends through both such interdigitated metal layers. In the example shown in FIG. 2A, metal layer 210, which is in metal stack 237, is partially overlapping in the vertical direction with metal layer 293, which is in metal stack 242. Thus, the metal layers 210 and 293 are interdigitated with each other. Similarly, the metal layer 292, which is in metal stack 242, is partially overlapping in the vertical direction with metal layer 294, which is in metal stack 236. Thus, metal layers 292 and 294 are interdigitated with each other. Likewise, the metal layer 294, which is in metal stack 236, is partially overlapping in the vertical direction with metal layer 224, which is in metal stack 241. Thus, metal layers 294 and 224 are interdigitated with each other.

When any two metal layers are interdigitated with each other, the interdigitation blocks the propagation of cracks that may form in the dielectric material 206. For example, if a crack were to form in the dielectric material 206 at the top of the substrate 205 between solder bumps 220 and 234, a lack of interdigitation between the metal stacks 236, 241 leaves a pathway for the crack to propagate downward toward the bottom of the substrate 205, between the metal stacks 236, 241. However, because the metal layers 294, 224 are interdigitated with each other, any such formed crack will be blocked from propagating between the metal stacks 236, 241, because when the propagating crack encounters either of the interdigitated metal layers 294, 224, the metal layer(s) will arrest the crack propagation. In this way, interdigitation preserves the mechanical and functional integrity of the semiconductor package 104. Any suitable number of metal layers may be interdigitated in this manner. Interdigitated metal layers may be in the same metal stack or in different metal stacks. However, they cannot be co-located at the same vertical level, meaning that interdigitated metal layers must be vertically offset from each other such that they can vertically overlap with each other as described above without coming into contact with each other (thus avoiding short circuits).

One or more of the metal layers in the substrate 205 may include notches. A notch is a cavity in a top surface of a metal layer in the substrate 205 and/or in a combination of top and lateral surfaces of a metal layer in the substrate 205 (i.e., on a metal layer edge at which the top and lateral surfaces of a metal layer meet). In FIG. 2A, various metal layers include such notches. For example, metal layer 208 includes a notch 290 in the top and lateral surfaces of the metal layer 208. Metal layer 210 includes a notch 290 in the top surface of the metal layer 210. Metal layer 214 includes a notch 290 in the top and lateral surfaces of the metal layer 214. Metal layer 222 includes two notches 290, with a first notch 290 formed in the top surface and a first lateral surface of the metal layer 222, and with a second notch 290 formed in the top surface and a second lateral surface of the metal layer 222, as shown. As described below, notches 290 are formed by etching, and thus each notch 290 has a curved interior surface. The notches 290 are filled by dielectric material 206. The depth and specific shape of each notch 290 may vary depending on the specific etching process used to form the notch 290. Because the notches 290 may be formed by etching, the notches 290 are present on the top surface and/or the top and lateral surfaces of the metal layers in the substrate 205, and are not present on the bottom surface or only on lateral surfaces. However, in some examples, the notches 290 may be formed solely on the lateral surfaces of one or more of the metal layers of the substrate 205, on the bottom surface of one or more of the metal layers of the substrate 205, and/or a combination thereof. In such examples, the notches 290 may be formed using a technique other than etching. For example, the notches 290 may be formed in pre-fabricated metal layers that are subsequently used to form the substrate 205.

FIG. 2B is a top-down view of the semiconductor package 104 with notched, interdigitated, and retracted metal layers, in accordance with various examples. FIG. 2C is a perspective view of the semiconductor package 104 with notched, interdigitated, and retracted metal layers, in accordance with various examples. FIG. 2D is a profile view of the semiconductor package 104 with notched, interdigitated, and retracted metal layers, in accordance with various examples. FIG. 2E is a bottom-up view of the semiconductor package 104 with notched, interdigitated, and retracted metal layers, in accordance with various examples.

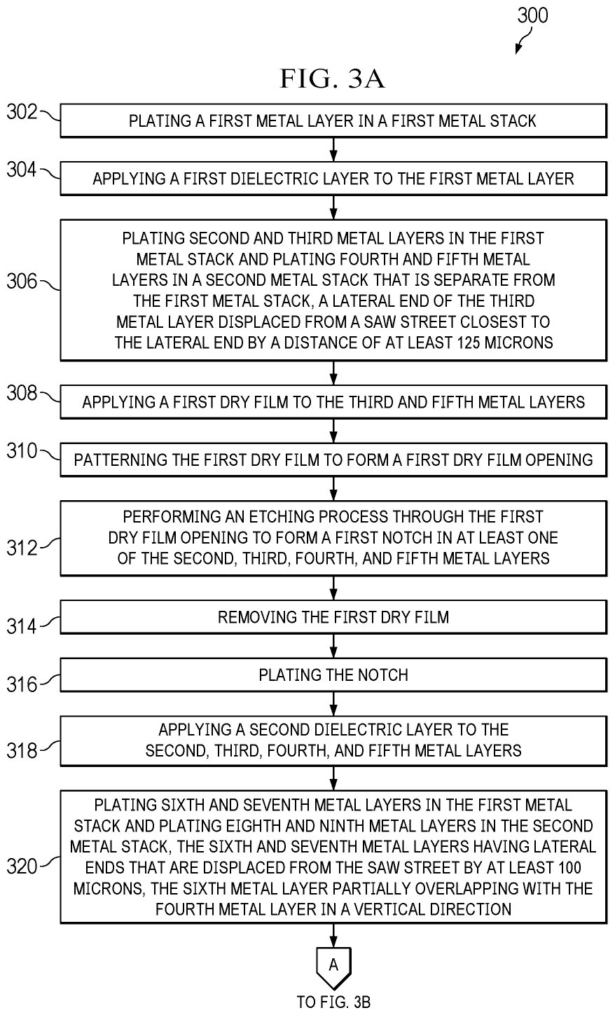

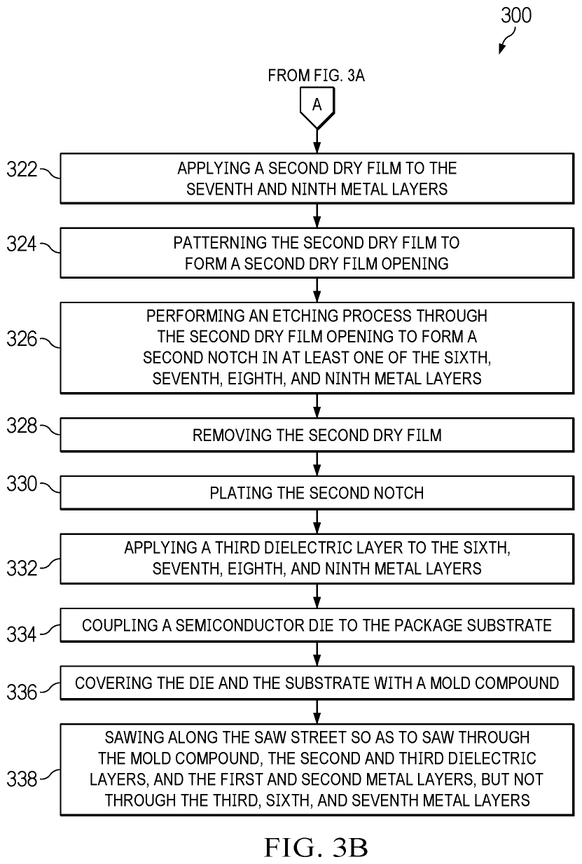

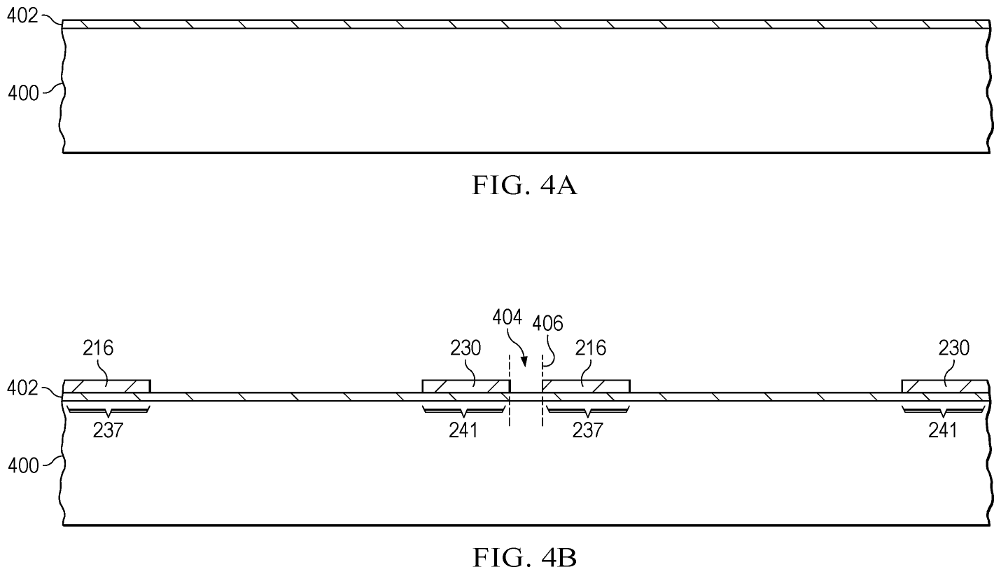

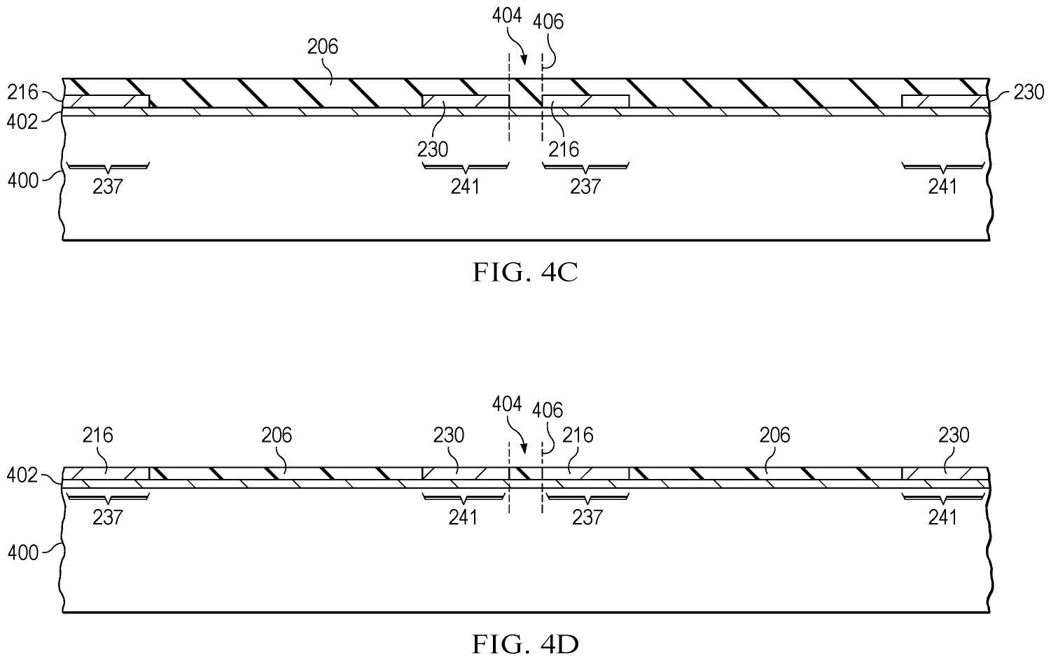

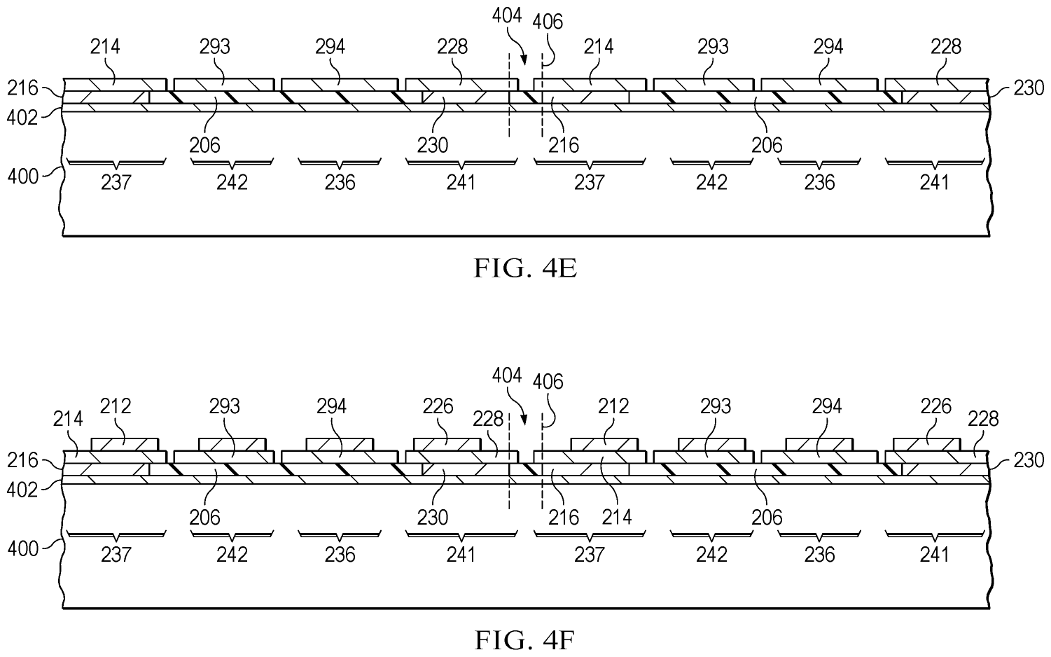

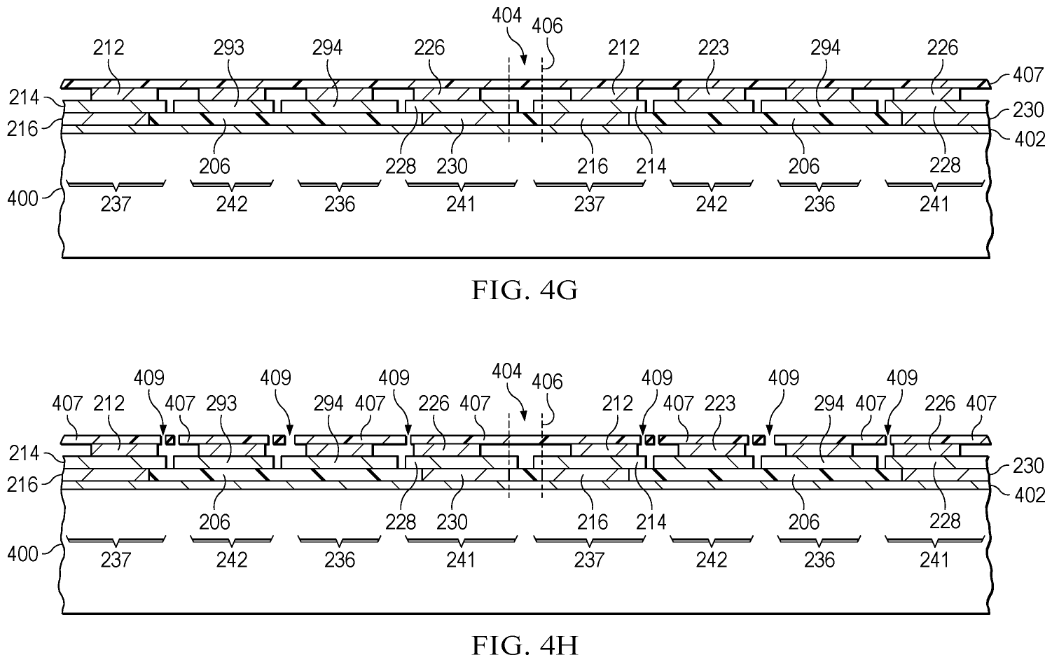

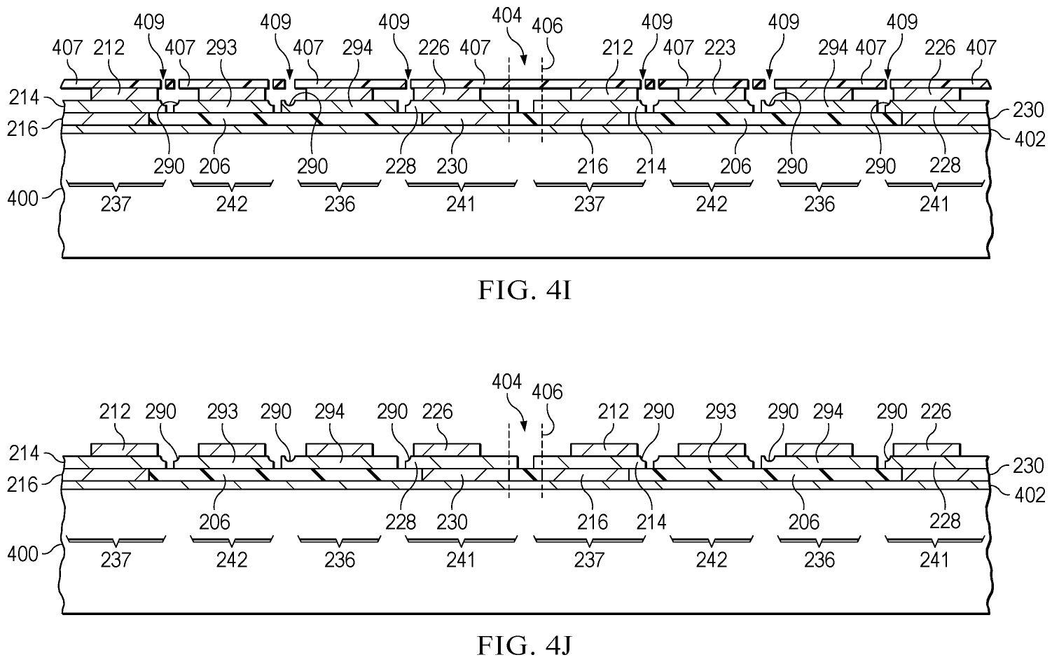

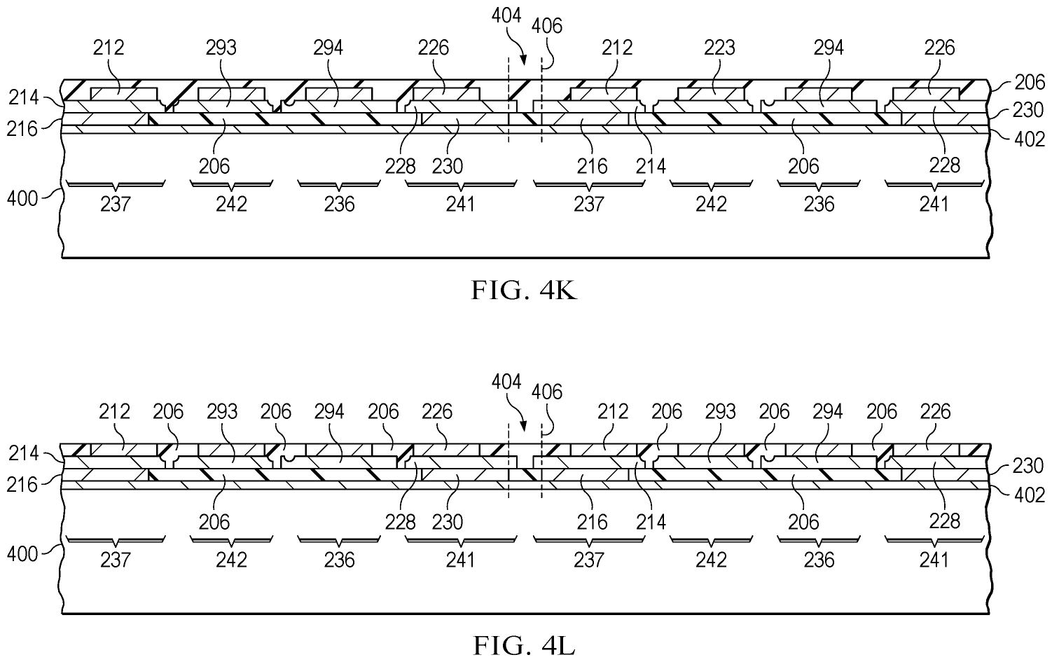

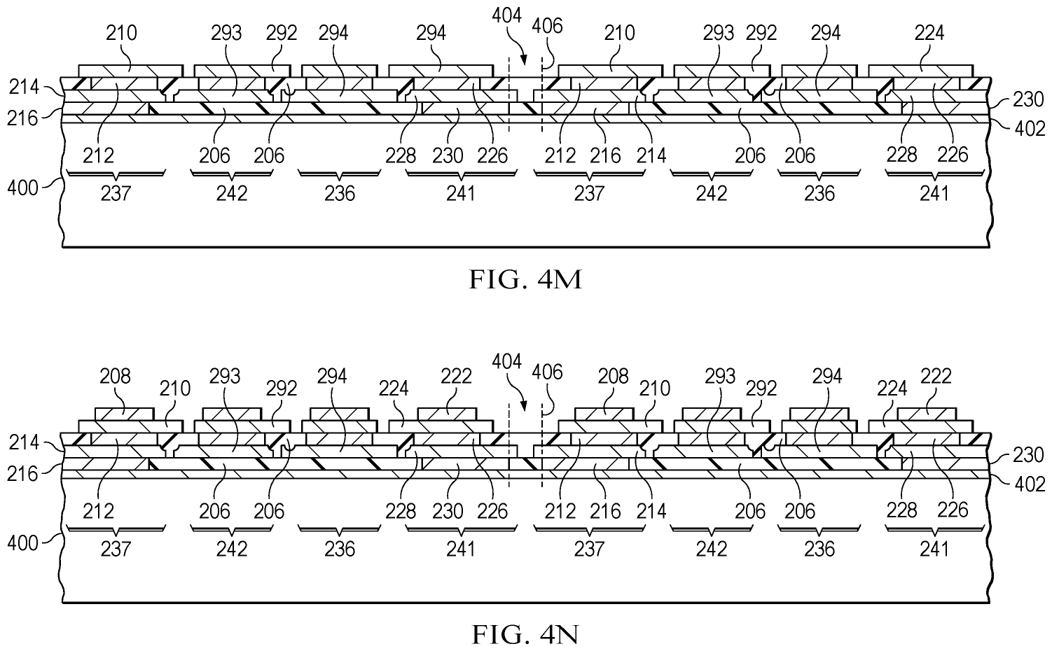

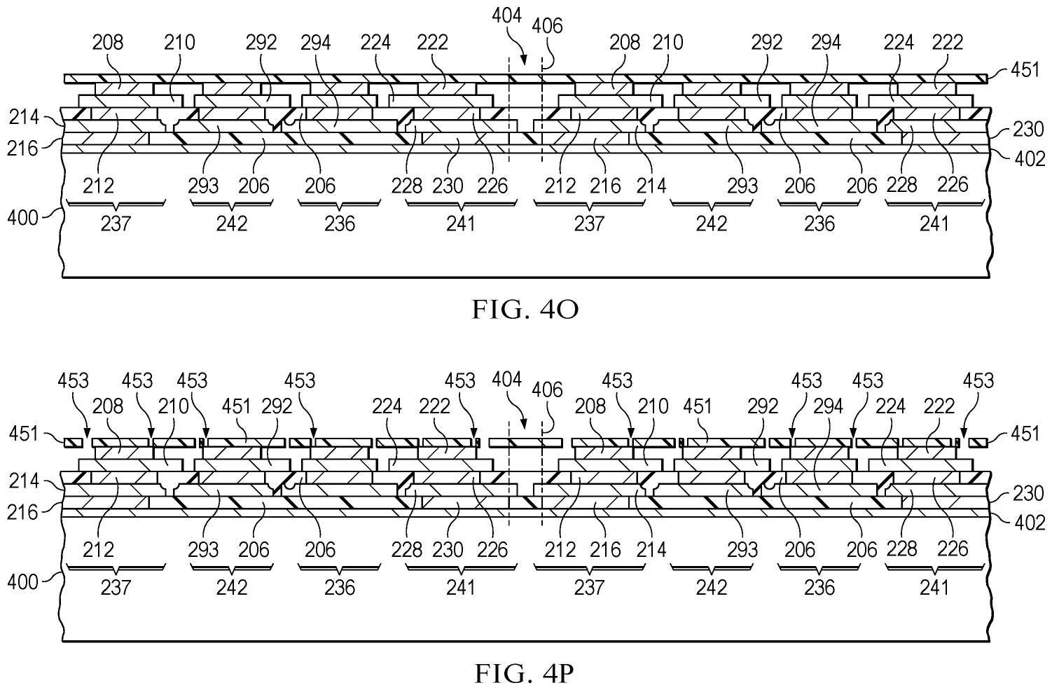

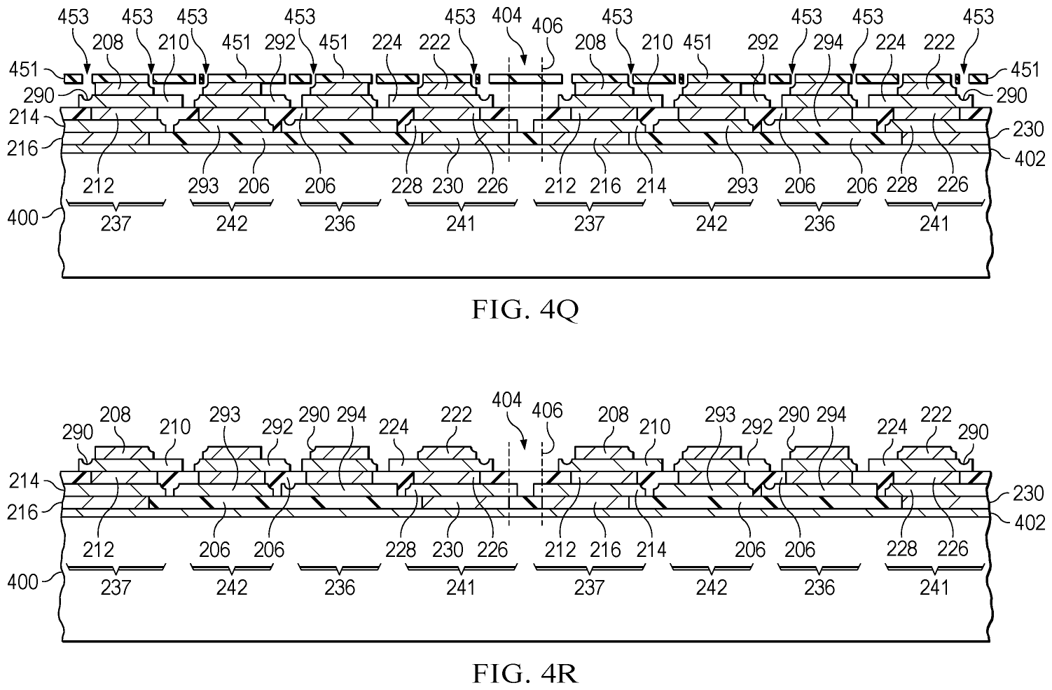

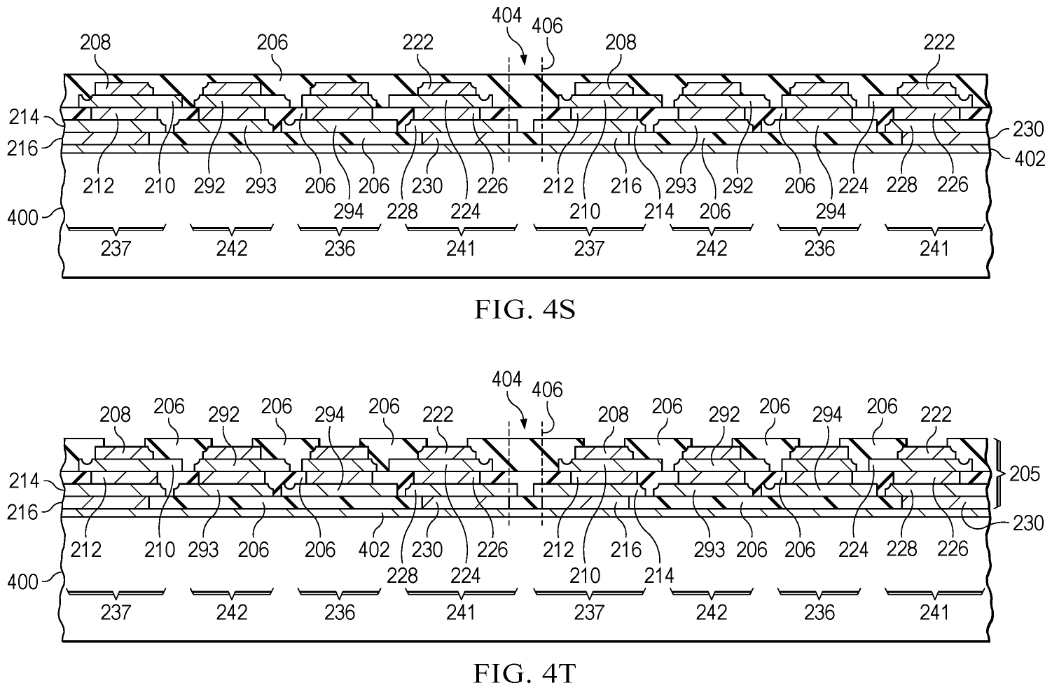

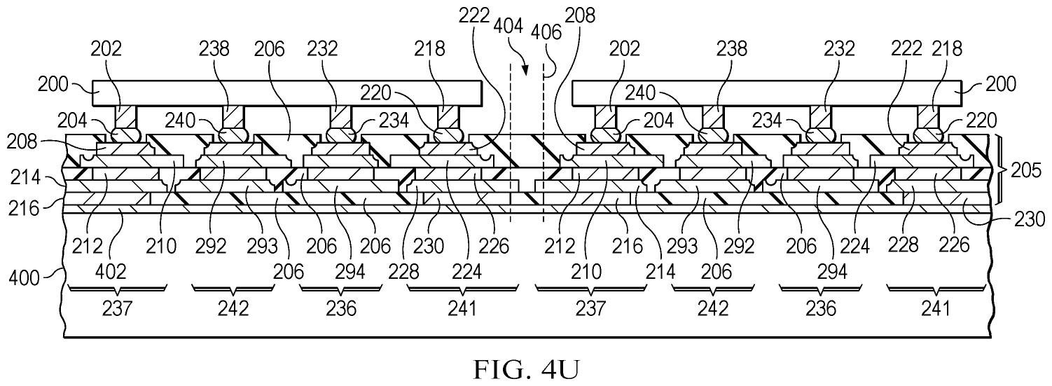

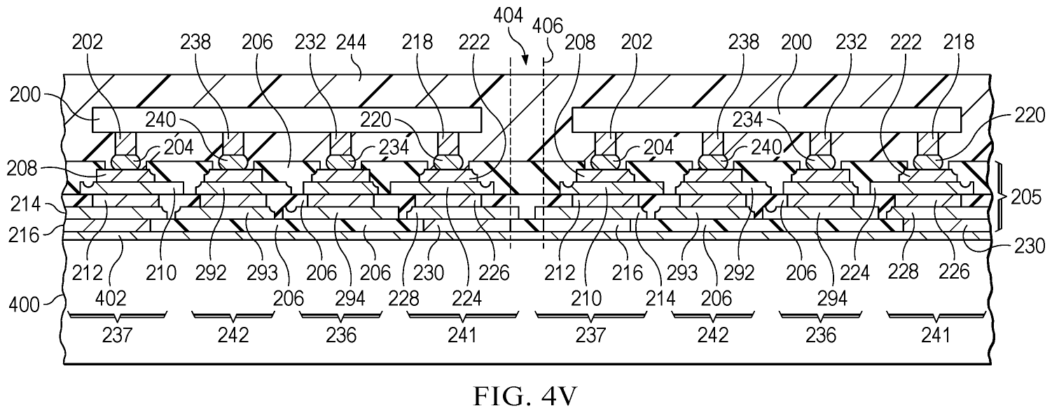

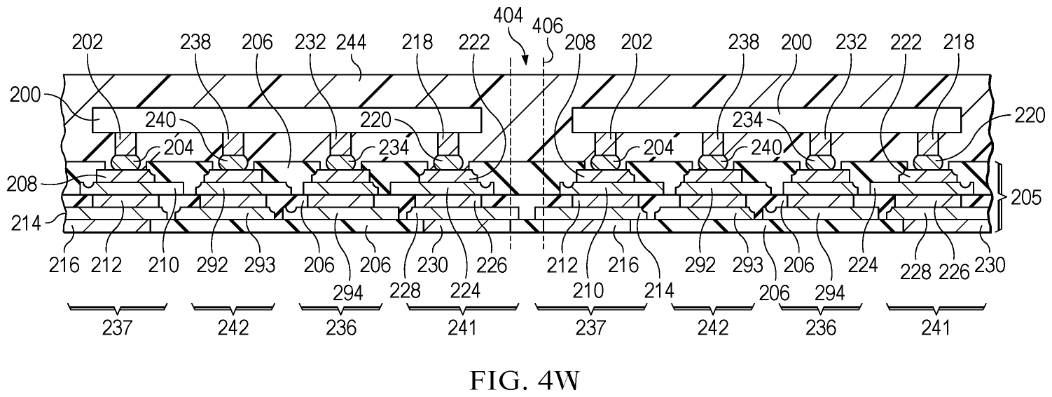

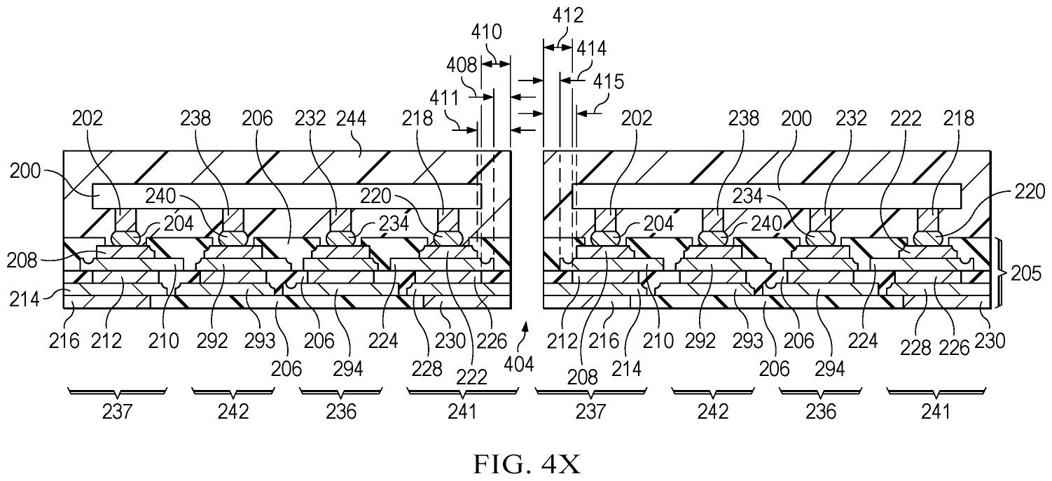

FIGS. 3A and 3B are a flow diagram of a method 300 for manufacturing a semiconductor package (e.g., the package 104) with notched, interdigitated, and retracted metal layers, in accordance with various examples. The method 300 includes plating a first metal layer in a first metal stack (302) and applying a first dielectric layer to the first metal layer (304). FIG. 4A shows a seed layer 402 deposited (e.g., sputtered) on a substrate 400. FIG. 4B shows the plating of metal layer 216 in metal stack 237 and metal layer 230 in metal stack 241. FIG. 4B shows two instances of metal layers 216 and two instances of metal layers 230 because the example process flow of FIGS. 4A-4X depicts the manufacture of multiple (e.g., two) semiconductor packages 104. Interfaces 406 indicate the location of a saw street 404 along which a cut will subsequently be made. The location of the saw street 404 is shown throughout the process flow of FIGS. 4A-4X to demonstrate the retraction of the various metal layers as described above.

FIG. 4C shows the structure of FIG. 4B, but with dielectric material 206 deposited on the metal layers 216 and 230 (e.g., by lamination). The dielectric material 206 may be deposited to be thicker than the metal layers 216 and 230, as shown. Thus, as FIG. 4D shows, a grinding process may be used to reduce the thickness of the dielectric material 206 so the top surfaces of the metal layers 216 and 230 are exposed through the top surface of the dielectric material 206, thus facilitating further plating of additional metal layers on the metal layers 216 and 230.

The method 300 includes plating second and third metal layers in the first metal stack and plating fourth and fifth metal layers in a second metal stack that is separate from the first metal stack (306). A lateral end of the third metal layer is displaced from a saw street closest to the lateral end by a distance of at least 100 microns (306). FIG. 4E shows metal layers (e.g., traces) 214 and 228 plated on metal layers 216 and 230, respectively. Together, the metal layers 214 and 216 begin to form the metal stack 237, and the metal layers 228 and 230 begin to form the metal stack 241. Additional metal layers are also formed in metal stacks 236 and 242, as shown. Also as FIG. 4E shows, the metal layers 228 and 230 (on the left) and the metal layers 214 and 216 (on the right) interface with the saw street 404. These lower-most metal layers must interface with the saw street 404 so that, post-singulation, the metal layers may serve as conductive terminals useful to couple to the PCB 102 (e.g., by soldering). Otherwise, the semiconductor package 104 would not have an electrical pathway by which to exchange signals with the PCB 102. FIG. 4F shows the plating of metal layers (e.g., vias) 212 and 226 in metal stacks 237 and 241, respectively. The metal layer 226 (on the left) and the metal layer 212 (on the right) are laterally spaced at least 125 microns from their respective interfaces 406, which indicate the closest respective interfaces with the saw street 404.

The method 300 includes applying a first dry film to the third and fifth metal layers (308). FIG. 4G shows the application of a dry film 407 to the topmost metal layers in each of the metal stacks 236, 237, 241, and 242. The dry film 407 may be, for example, resists or polyimide film, etc. The dry film 407 may be applied, for example, by lamination. The method 300 includes patterning the first dry film to form a first dry film opening (310). FIG. 4H shows the dry film 407 having been patterned to include multiple dry film openings 409. The dry film 407 may be patterned using any suitable technique, such as photolithography, laser ablation, and mechanical patterning. The method 300 includes performing an etching process through the first dry film opening to form a first notch in at least one of the second, third, fourth, and fifth metal layers (312), removing the first dry film (314), and plating the notch (316). FIG. 4I shows the structure of FIG. 4H, but with the etching of notches 290 in various metal layers through the dry film openings 409. FIG. 4J shows the structure of FIG. 4I, but with dry film 407 having been removed. The notches 290 may be plated, for example, with tin or another suitable metal or alloy.

The method 300 includes applying a second dielectric layer to the second, third, fourth, and fifth metal layers (318). FIG. 4K shows the structure of FIG. 4J, but with the addition of dielectric material 206. FIG. 4L shows the structure of FIG. 4K, but with the additional dielectric material 206 having been grinded down so that the top surfaces of the metal stacks are approximately flush with the top surface of the dielectric material 206.

The method 300 includes plating sixth and seventh metal layers in the first metal stack and plating eighth and ninth metal layers in the second metal stack (320). The sixth and seventh metal layers have lateral ends that are displaced from the saw street by at least 100 microns (320). The sixth metal layer partially overlaps with the fourth metal layer in the vertical direction (320). FIG. 4M shows the structure of FIG. 4L, but with the further plating of an additional metal layer on the top of each metal stack 236, 237, 241, 242, as shown. For example, metal layers 224 are plated on metal stacks 241, and metal layers 210 are plated on metal stacks 237. Further, FIG. 4N shows the structure of FIG. 4M, but with the further plating of an additional metal layer on the top of each metal stack 236, 237, 241, 242, as shown. For example, metal layers 208 are plated on metal stacks 237, and metal layers 222 and plated on metal stacks 241. The edges of metal layers 224, 210 closest to the respective interfaces 406 are spaced apart from their respective interface 406 by a minimum of 100 microns to achieve the mechanical stress mitigation described above. The edges of metal layers 208, 222 closest to the respective interfaces 406 are spaced apart from their respective interface 406 by a minimum of 125 microns to achieve the mechanical stress mitigation described above.

The method 300 includes applying a second dry film to the seventh and ninth metal layers (322) and patterning the second dry film to form a second dry film opening (324). FIG. 4O shows the structure of FIG. 4N, but with the addition of a dry film 451 positioned on the topmost metal layers of the metal stacks 236, 237, 241, and 242. FIG. 4P shows the structure of FIG. 4O, but with the patterning of the dry film 451 by the formation of multiple dry film openings 453 in the dry film 451.

The method 300 includes performing an etching process through the second dry film opening to form a second notch in at least one of the sixth, seventh, eighth, and ninth metal layers (326), followed by removing the second dry film (328) and plating the second notch (330). FIG. 4Q shows the structure of FIG. 4P, but with an etching process being performed through the dry film openings 453 to form the various notches 290. FIG. 4R shows the structure of FIG. 4Q, but with the dry film 451 removed. The notches 290 may be plated with a suitable metal or alloy, such as tin.

The method 300 includes applying a third dielectric layer to the sixth, seventh, eighth, and ninth metal layers (332). FIG. 4S shows the application of additional dielectric material 206 on the substrate, and FIG. 4T shows the formation of orifices in the top surface of the dielectric material 206, directly above the top-most metal layers in each of the metal stacks 236, 237, 241, and 242.

The method 300 includes coupling a semiconductor die to the package substrate (334), covering the die and the substrate with a mold compound (336), and sawing along the saw street so as to saw through the mold compound, the second and third dielectric layers, and the first and second metal layers, but not through the third, sixth, and seventh metal layers (338). FIG. 4U shows the structure of FIG. 4T, except with semiconductor dies 200 coupled to the topmost metal layers of the metal stacks 236, 237, 241, and 242 by conductive members 232, 202, 218, and 238 and solder bumps 234, 204, 220, and 240, respectively. FIG. 4V shows the structure of FIG. 4U, but with the application of the mold compound 244. FIG. 4W shows the removal of the substrate 400, and FIG. 4X shows the sawing along the saw street 404, in accordance with various examples. The metal layers 226, 224, and 222 are laterally offset away from the closest interface 406 of the saw street 404 by distances 410, 408, and 411, respectively, each of which is at least 100 microns, and in the case of distances 410 and 411, at least 125 microns. As explained, these minimum distances are critical to achieve the benefits of the metal layer retreats described herein. Similarly, the metal layers 212, 210, and 208 are laterally offset away from the closest interface 406 of the saw street 404 by distances 412, 414, and 415, respectively, each of which is at least 100 microns, and in the case of distances 412 and 415, at least 125 microns. As explained, these minimum distances are critical to achieve the benefits of the metal layer retreats described herein. In some examples, the distance 410 is greater than distance 408, and the distance 412 is greater than distance 414. Because the saw tool does not cut through metal layers 222, 224, or 226 (on the left side) or metal layers 208, 210, or 212 (on the right side), the stresses that would otherwise have been imparted are mitigated, as are the consequences of such stresses. For example, the interface between the dielectric material 206 and the mold compound 244 may be entirely devoid of delamination.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A package, comprising:
a semiconductor die having a device side including circuitry formed therein;
a substrate facing and coupled to the device side, the substrate including:
first and second metal layers, the first metal layer positioned closer to the device side than the second metal layer and coupled to the second metal layer by way of a via, at least one of the first and second metal layers having a top surface facing the semiconductor die, the top surface including a notch etched therein; and
a dielectric contacting the notch and at least part of the first and second metal layers and the via; and
a mold compound covering the semiconductor die and the substrate,
wherein the package includes a lateral surface approximately perpendicular to the first and second metal layers of the substrate, and wherein the mold compound, the dielectric, and the second metal layer are exposed to the lateral surface, a segment of the dielectric positioned between the first metal layer and the lateral surface, the segment of the dielectric contacting the mold compound at the lateral surface.

2. The package of claim 1, wherein the at least one of the first and second metal layers includes a lateral surface facing the lateral surface of the package, and wherein the notch coincides with the top surface and with the lateral surface of the at least one of the first and second metal layers.

3. The package of claim 1, wherein the at least one of the first and second metal layers includes a bottom surface, and wherein the bottom surface does not have a notch etched therein.

4. The package of claim 1, further comprising:
third and fourth metal layers in the substrate, the third metal layer positioned closer to the device side than the fourth metal layer, the third and fourth metal layers spaced apart from the first and second metal layers, the first metal layer at least partially overlapping the fourth metal layer in the vertical direction, the first and fourth metal layers in different levels of the substrate.

5. The package of claim 1, wherein the dielectric fills the notch.

6. The package of claim 1, wherein the dielectric includes AJINOMOTO® build-up film (ABF).

7. A package, comprising:
a semiconductor die having a device side including circuitry formed therein;
a substrate coupled to the device side, the substrate including a first level, a second level, a first metal stack, and a second metal stack, the first metal stack including a first set of contiguous metal structures of the first and second levels, the second metal stack including a second set of contiguous metal structures of the first and second levels, the first and second metal stacks spaced apart from one another, a first metal layer of the first metal stack partially overlapping a second metal layer of the second metal stack, and the first and second metal layers in different levels of the substrate, wherein at least one of the first and second metal stacks includes a metal layer having a top surface comprising an etched notch, the substrate further comprising a dielectric covering the first and second metal stacks and contacting the etched notch; and
a mold compound covering the die and the substrate.

8. The package of claim 7, wherein the metal layer includes a lateral surface orthogonal to the top surface, and wherein the etched notch coincides with the top and lateral surfaces of the metal layer.

9. The package of claim 7, wherein the top surface of the metal layer faces the device side.

10. The package of claim 7, wherein the first and second metal stacks do not include any metal layer having a bottom surface facing away from the device side and having an etched notch.

11. The package of claim 7, wherein the dielectric fills the etched notch.

12. The package of claim 7, wherein the dielectric includes AJINOMOTO® build-up film (ABF).

13. The package of claim 7, wherein:
the first metal stack includes the first metal layer and a third metal layer, the first metal layer closer to the die than the third metal layer,
the package includes a lateral surface, the first and third metal layers are offset from the lateral surface by at least 100 microns, and
the dielectric contacts the mold compound at the lateral surface.

14. A package, comprising:
a semiconductor die having a device side including circuitry formed therein;
a substrate facing and coupled to the device side, the substrate including:
first and second metal layers, the first metal layer coupled to the second metal layer by way of a via, the first metal layer having a top surface facing the die, the top surface of the first metal layer including a first notch etched therein, the second metal layer having a top surface facing the die and a lateral surface orthogonal to the top surface, the top and lateral surfaces of the second metal layer having a second notch etched therein; and
a dielectric contacting at least part of the first and second metal layers and the via; and
a mold compound covering the semiconductor die and the substrate.

15. The package of claim 14, wherein the dielectric fills the first and second notches.

16. The package of claim 14, wherein the notches are plated with tin.

17. The package of claim 14, further comprising:
third and fourth metal layers in the substrate, the third metal layer positioned closer to the device side than the fourth metal layer, the third and fourth metal layers spaced apart from the first and second metal layers, the first metal layer at least partially overlapping the fourth metal layer in the vertical direction, the first and fourth metal layers in different levels of the substrate.

18. The package of claim 14, wherein:
the package includes a lateral surface, the first and second metal layers are offset from the lateral surface by at least 100 microns, and
the dielectric contacts the mold compound at the lateral surface.

19. The package of claim 14, wherein the dielectric includes AJINOMOTO® build-up film (ABF).

20. A package, comprising:
a semiconductor die having a device side including circuitry formed therein;
a substrate facing and coupled to the device side, the substrate including:
first and second metal layers, the first metal layer positioned closer to the device side than the second metal layer and coupled to the second metal layer by way of a via, at least one of the first and second metal layers having a top surface facing the semiconductor die, the top surface including a notch etched therein;
third and fourth metal layers, the third metal layer positioned closer to the device side than the fourth metal layer, the third and fourth metal layers spaced apart from the first and second metal layers, the first metal layer at least partially overlapping the fourth metal layer in the vertical direction, the first and fourth metal layers in different levels of the substrate; and
a dielectric contacting at least part of the first and second metal layers and the via; and
a mold compound covering the semiconductor die and the substrate,
wherein the package includes a lateral surface approximately perpendicular to the first and second metal layers of the substrate, and wherein the mold compound, the dielectric, and the second metal layer are exposed to the lateral surface, a segment of the dielectric positioned between the first metal layer and the lateral surface, the segment of the dielectric contacting the mold compound at the lateral surface.

21. The package of claim 20, wherein the dielectric fills the notch.

22. The package of claim 20, wherein the at least one of the first and second metal layers also includes a lateral surface orthogonal to the top surface, the notch coincident with both the top and lateral surfaces of the at least one of the first and second metal layers.

23. The package of claim 20, wherein the notch is plated with tin.

24. The package of claim 20, wherein the dielectric includes AJINOMOTO® build-up film (ABF).

25. A method of manufacturing a package, comprising:
forming a package substrate, comprising:
plating first and second metal layers in a first metal stack and a third metal layer in a second metal stack, the second metal layer having a lateral end that is displaced from a saw street closest to the lateral end by a distance of at least 100 microns, at least one metal layer in the first metal stack partially overlapping in a vertical direction with the third metal layer;
applying a dry film to at least one of the first, second, and third metal layers;
patterning the dry film to form a dry film opening;
etching at least one of the first, second, and third metal layers through the dry film opening to form a notch;
removing the dry film;
plating the notch; and
applying a dielectric layer to at least one of the first, second, and third metal layers;
coupling a semiconductor die to the package substrate;
covering the die and the substrate with a mold compound; and
sawing along the saw street so as to saw through the mold compound and the dielectric layer, but not through the second metal layer.

26. The method of claim 25, wherein the dielectric layer comprises AJINOMOTO® build-up film (ABF).

27. The method of claim 25, wherein the dielectric layer fills the notch.

28. The method of claim 25, wherein plating the notch comprises plating the notch with tin.
